(19) United States
(12) Patent Application Publication
(10) Pub. No.: US 2021/0091280 A1
(43) Pub. Date: Mar. 25, 2021

(54) LED CHIP STRUCTURE, MANUFACTURING METHOD THEREOF, AND MASS TRANSFER METHOD APPLYING THE LED CHIP STRUCTURE

(71) Applicant: Dongguan Institute of Opto-Electronics, Peking University, Dongguan City (CN)

(72) Inventors: Chengming LI, Dongguan City (CN); Qi WANG, Dongguan City (CN); Guoyi ZHANG, Dongguan City (CN)

(21) Appl. No.: 16/921,587

(22) Filed: Jul. 6, 2020

(30) Foreign Application Priority Data
Sep. 19, 2019 (CN) 201910886342.0

(51) Int. Cl. H01L 33/62; H01L 25/075; H01L 33/00

(52) U.S. Cl. CPC H01L 33/62; H01L 25/0753; H01L 2933/0066; H01L 33/0093; H01L 33/0091

(57) ABSTRACT

Disclosed are an LED chip structure and its manufacturing method, and a mass transfer method applying the LED chip structure. The LED chip structure includes a substrate, a light emitting unit connected to the substrate, a passivation layer, an ohmic contact layer, and a metal layer formed at the junction of the light emitting unit and the substrate. The passivation layer surrounds the periphery of the light emitting unit and is connected to the metal layer, and the ohmic contact layer is covered onto the passivation layer and connected to the light emitting unit. The LED chip structure has the features of reasonable design and convenient transfer; the manufacturing method has the features of simple manufacture process, easy manufacture, and compact LED chip structure; and the mass transfer method applying the LED chip structure has the features of simple operation, easy alignment, and convenient transfer.

### FIELD OF THE INVENTION

The present invention relates to the semiconductor technology, and more particularly to an LED chip structure and its manufacturing method, and a mass transfer method applying the LED chip structure.

### BACKGROUND OF THE INVENTION

Light emitting diode (LED) with the advantages of small volume, low power, long service life, high brightness and active light emission is widely used in the areas of illumination and display. Micro LED, also known as mini LED, mLED or μLED, is a novel tablet display technology. Compared with the popular liquid crystal display device, the micro LED display device having an LED array with independent primitive components has better contrast, faster response speed and lower power consumption.

Since the micro LED is manufactured individually, therefore it is necessary to transfer a very large amount of micro LED chips onto a substrate in the manufacturing process of the display devices. At present, the conventional mass transfer method of the micro LED chips mainly includes the steps of single micro LED chip access and transfer, fluid assembly, liquid surface self-assembly, electrostatic self-assembly, laser transfer, etc. In view of the relatively small size of the micro LED chips, it is uneasy to transfer the chips during the manufacturing process. In addition, the level of difficulty of the mass transfer is further increased when the electrode alignment of the micro LED chips is taken into account.

### SUMMARY OF THE INVENTION

In view of the aforementioned drawbacks and deficiencies of the prior art, it is a primary objective of the present invention to provide an LED chip structure, its manufacturing method, and a mass transfer method applying the LED chip structure. In this invention, the LED chip structure has the features of reasonable design and convenient transfer; the manufacturing method has the features of simple manufacture process, easy manufacture, and compact LED chip structure; and the mass transfer method applying the LED chip structure has the features of simple operation, easy alignment, and convenient transfer.

To achieve the aforementioned and other objectives, the present invention discloses an LED chip structure comprising a substrate, a light emitting unit coupled to the substrate, a passivation layer, an ohmic contact layer, and a metal layer disposed at the junction of the light emitting unit and the substrate, wherein the passivation layer is disposed around the periphery of the light emitting unit and coupled to the metal layer, and the ohmic contact layer is covered onto the passivation layer and coupled to the light emitting unit.

Wherein, the light emitting unit comprises an LED epitaxial layer, a bonding layer and a buffer layer installed sequentially, and the LED epitaxial layer is coupled to the metal layer.

Wherein, the substrate is made of an etchable material.

Wherein, the substrate is made of silicone.

Wherein, the bonding layer is made of NiAu, and the outermost layer of the bonding layer has an Au layer.

A manufacturing method of the LED chip structure comprises the steps of:

S1: preparing an epitaxial structure; S2: setting a bonding layer onto the epitaxial structure to manufacture an epitaxial material having the bonding layer; S3: transferring the epitaxial material of S2 to a target substrate, and bonding the epitaxial material with the target substrate to form a bonding material; and S4: etching the bonding material of the step S3, wherein the bonding material is etched from a bonding layer on a side of the epitaxial material to a substrate to form an LED chip structure.

Wherein, the epitaxial structure comprises a sapphire substrate, a buffer layer and LED epitaxial layer installed sequentially.

Wherein, the sapphire substrate is removed after the epitaxial material and the target substrate in the step S3 are bonded.

In a mass transfer method applying the LED chip structure, the LED chip structure is implanted with a corresponding template, the substrate is removed, and the LED chip is transferred into a target base plate for die bonding.

Wherein, the template has a wax layer near the LED chip structure, and the target base plate has a limit structure for limiting the position of the LED chip structure, and during a mass transfer process, the LED chip to be implanted into the template is dipped into a liquid, and the target base plate is also placed into the liquid, and the buoyancy of the liquid pushes and delivers the target base plate to a position under the LED chip, and after the LED chip is completely engaged with the limit structure of the target base plate, the target base plate engaged with the LED chip is removed from the surface of the liquid, and the template is removed by the slightly melted part of the wax layer, and then a die bonding of the LED chip and the target base plate is performed, and finally the wax layer is completely melted and removed to complete the mass transfer of the LED chip structure.

The present invention has the following advantages:

1. The LED chip structure of the present invention comprises a substrate, a light emitting unit coupled to the substrate, a passivation layer, an ohmic contact layer, and a metal layer disposed at the junction of the light emitting unit and the substrate, and the passivation layer is disposed around the periphery of the light emitting unit and coupled to the metal layer, and the ohmic contact layer is covered onto the passivation layer and coupled to the light emitting unit, so that the LED chip structure of the present invention has a reasonable design of covering the ohmic contact layer onto the outer side of the structure to achieve the effects of avoiding the specific identification of the electrodes of the LED chips during the mass transfer process and reducing the level of difficulty of alignment to facilitate the transfer of the LED chips.

2. The manufacturing method of the present invention has the features of simple and convenient manufacturing processes including the bonding and etching processes of the materials to complete the manufacture of the LED chip, and the LED chip structure so manufactured is reasonably compact and good to use.

3. In the mass transfer method applying the LED chip structure in accordance with the present invention, the transferred structure is dipped in a liquid during the transfer process, and the mass transfer can be completed easily by the buoyancy of the liquid together with the limit structure, so as to avoid the conventional mass transfer that requires a precise alignment of the chips and prevent the position of a single chip from being shifted during the mass transfer, so that this method is convenient for transferring a large quantity of LED chips.

### BRIEF DESCRIPTION OF THE DRAWINGS

FIG. 1 is a schematic view of an LED chip structure of the present invention;

FIG. 2 is a schematic view of an epitaxial structure of the present invention;

FIG. 3 is a schematic view of an epitaxial material of the present invention;

FIG. 4 is a schematic view of a bonding material of the present invention;

FIG. 5 is a schematic view of the structure of FIG. 4 after a sapphire substrate is removed;

FIG. 6 is a schematic view of the structure of FIG. 5 after a template is implanted;

FIG. 7 is a schematic view of the structure of FIG. 6 after a target substrate is removed;

FIG. 8 is a schematic view of the structure of FIG. 7 after being transferred to a target base plate;

FIG. 9 is a schematic view of the structure of FIG. 8 after a template is removed; and

FIG. 10 is a schematic view of the structure of FIG. 9 after a wax layer is removed.

### BRIEF DESCRIPTION OF NUMERALS USED IN THE DRAWINGS

1: Target substrate; 2: Light emitting unit; 3: LED epitaxial layer; 4: Bonding layer; 5: Metal layer; 6: Passivation layer; 7: Ohmic contact layer; 8: Epitaxial structure; 9: Template; 10: Target base plate; 11: Wax layer; 12: Limit structure; 13: Sapphire substrate; 14: Buffer layer.

### DESCRIPTION OF THE PREFERRED EMBODIMENTS

The technical characteristics of the present invention will become apparent with the detailed description of preferred embodiments accompanied with the illustration of related drawings.

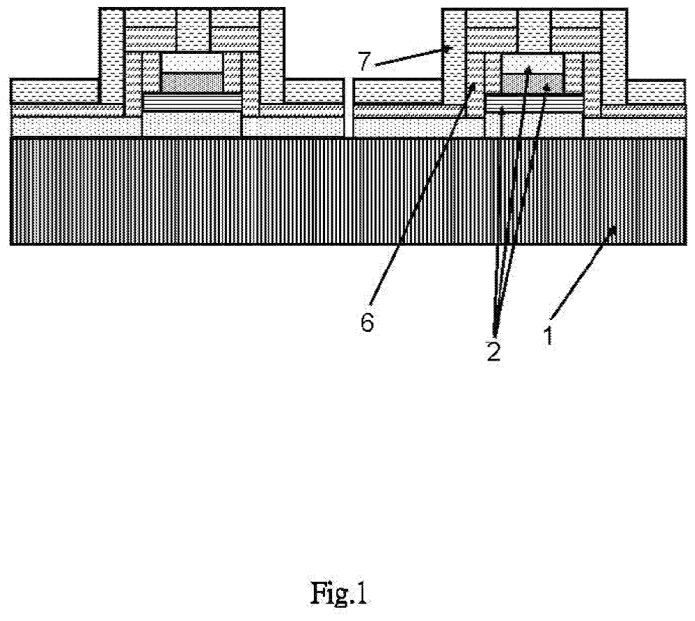

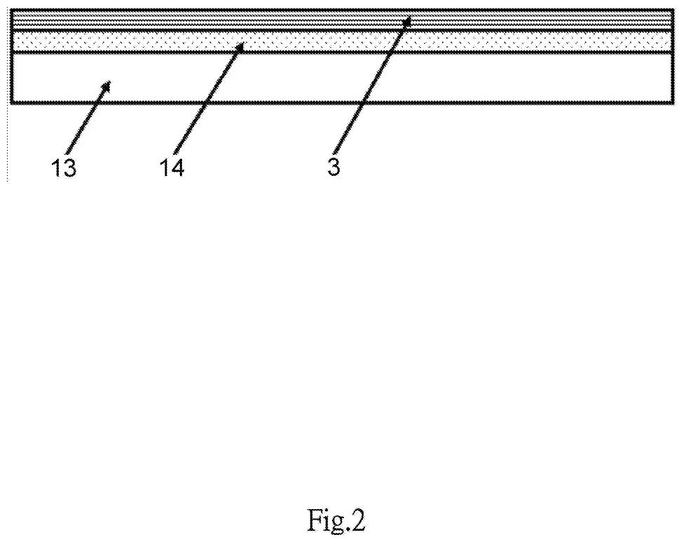

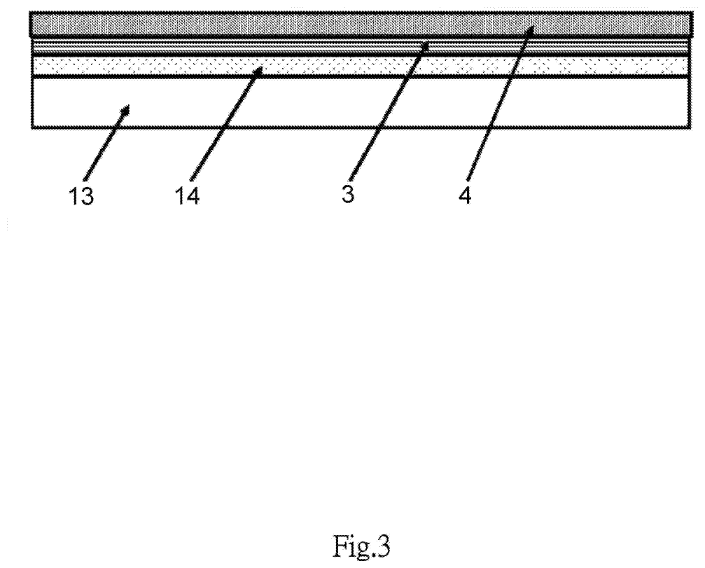

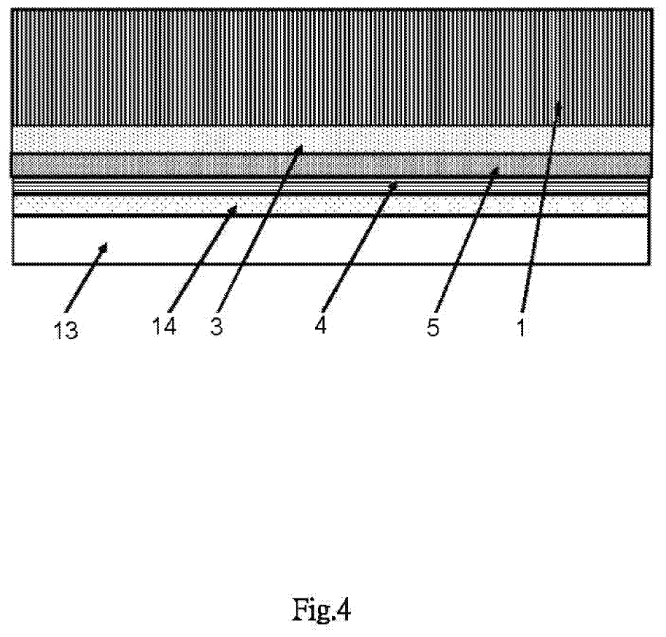

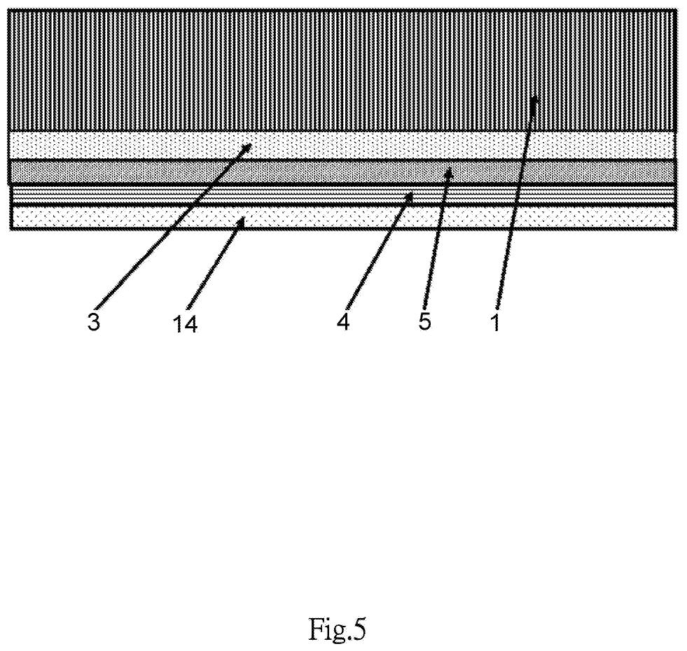

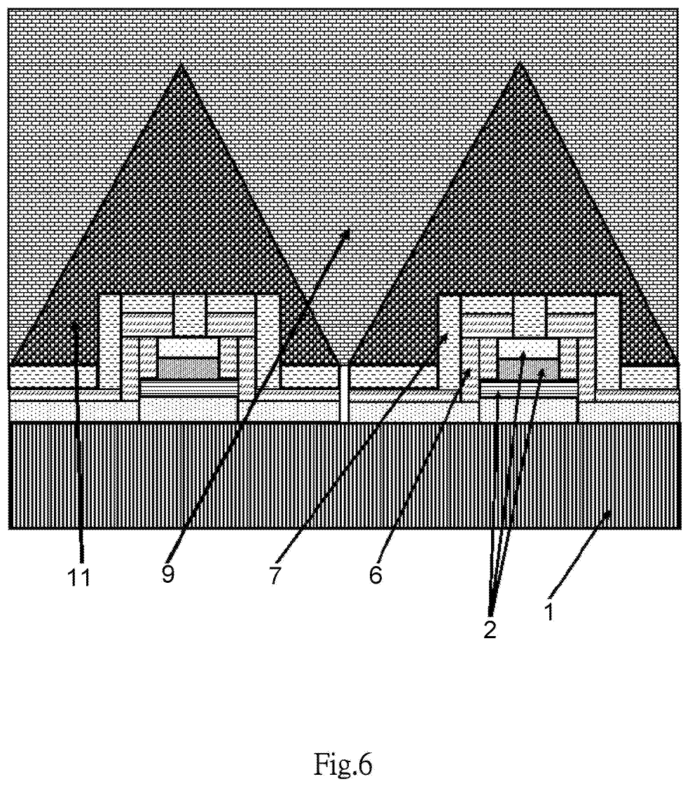

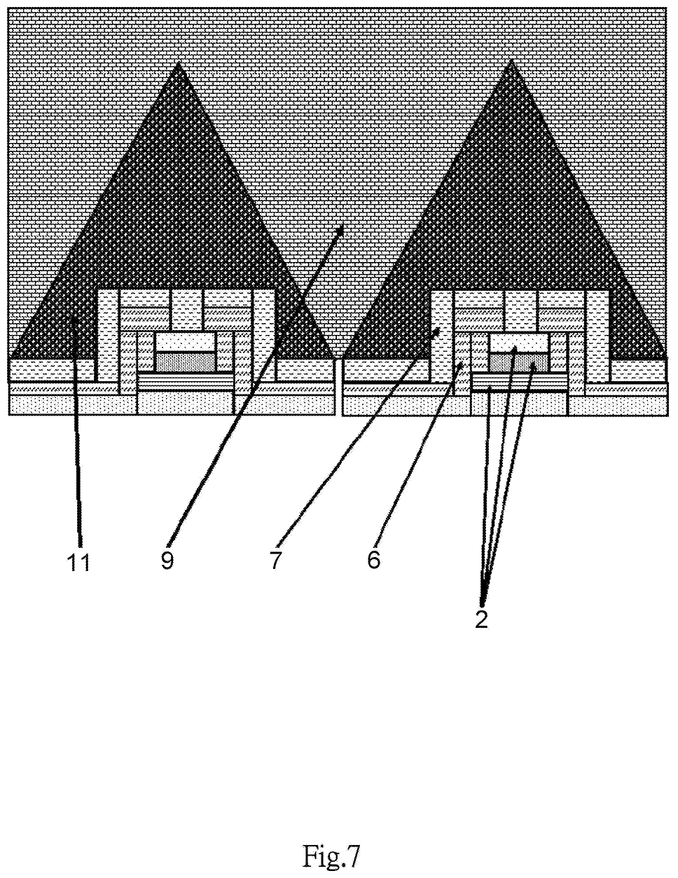

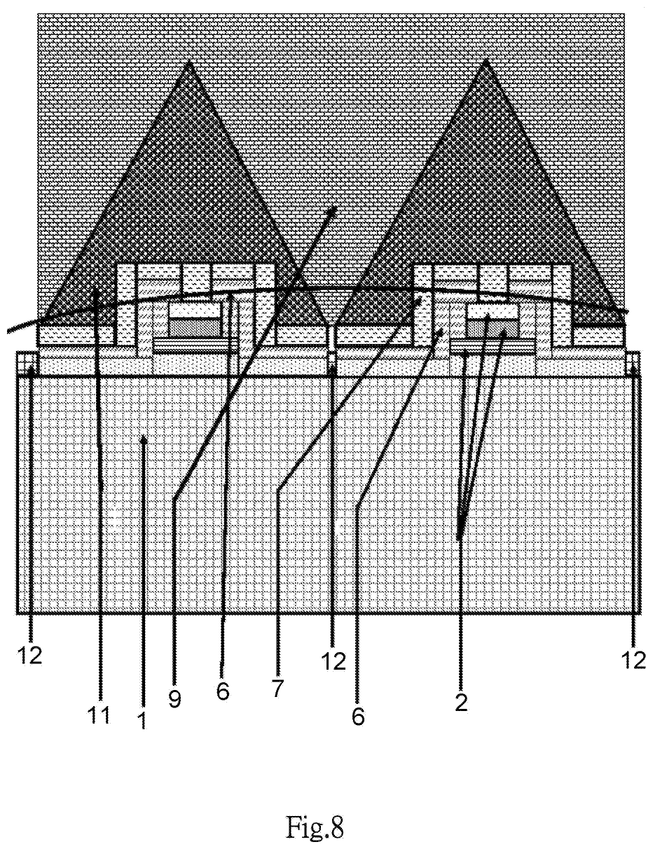

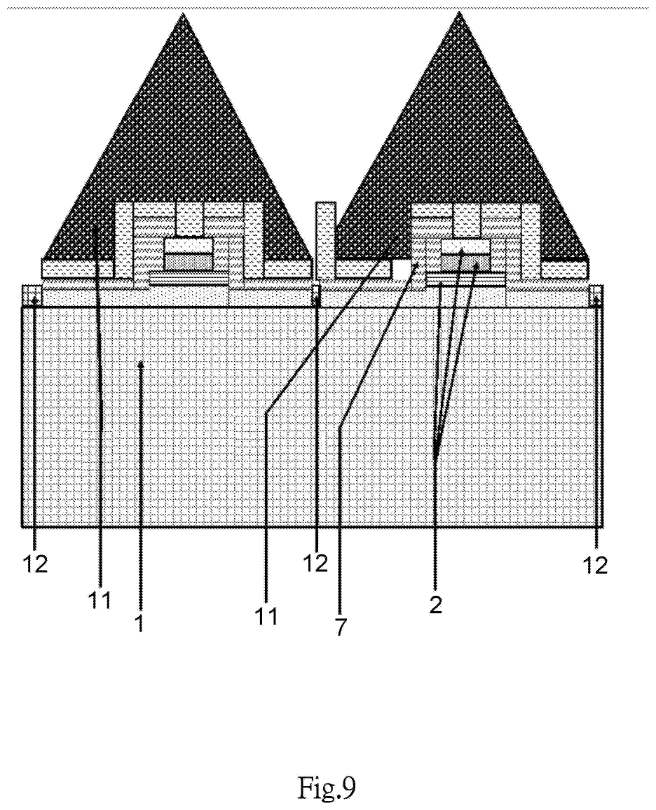

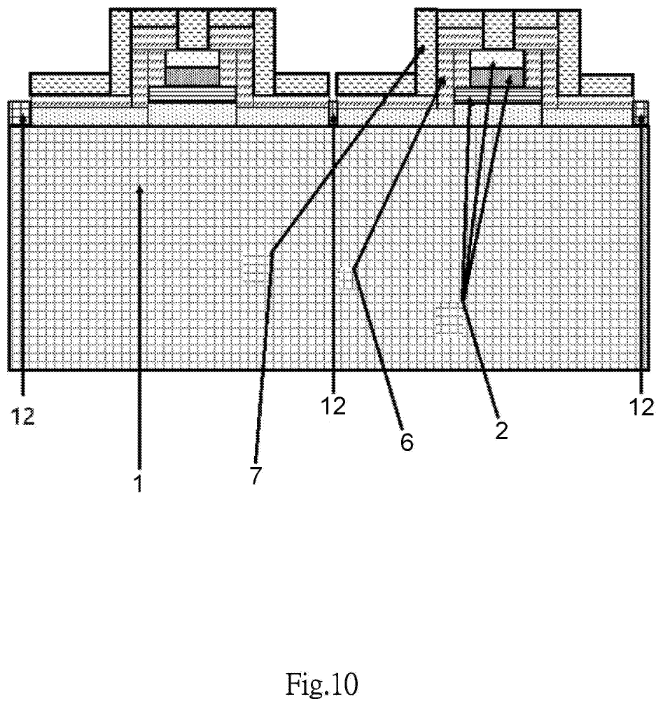

With reference to FIGS. 1 to 10 for an LED chip structure in accordance with an embodiment of the present invention, the LED chip structure comprises a substrate, a light emitting unit 2 coupled to the substrate, a passivation layer 6, an ohmic contact layer 7, and a metal layer 5 disposed at the junction of the light emitting unit 2 and the substrate, wherein the passivation layer 6 is disposed around the periphery of the light emitting unit 2 and coupled to the metal layer 5, and the ohmic contact layer 7 is covered onto the passivation layer 6 and coupled to the light emitting unit 2. The LED chip structure has a reasonable design of covering the ohmic contact layer 7 on the outside of the structure, so as to avoid the specific identification of the electrodes of the LED chips during the mass transfer process and reduce the level of difficulty of alignment to facilitate the transfer of the LED chips.

The light emitting unit 2 comprises an LED epitaxial layer 3, a bonding layer 4, and a buffer layer 14 installed sequentially, and the LED epitaxial layer 3 is coupled to the metal layer 5. Specifically, the buffer layer 14 of the present invention is composed of a GaN buffer layer 14 and a doped layer, and such arrangement can electrically connect the light emitting unit 2 with a circuit of an external substrate and achieve the effects of making the crystalline structure the same or similar, reducing the lattice mismatch, improving the crystallization performance, and decreasing the defect density.

The substrate is made of an etchable material, so that the etching process can be easier to reduce the level of difficulty of the manufacture. Specifically, the substrate is made of silicon directly, wherein the silicon selected is the conventional monocrystalline silicon.

The bonding layer 4 is made of NiAu, so that a better bonding can be achieved to prevent large lattice mismatch and thermal expansion mismatch when GaN and Si are bonded with each other directly, so that it is difficult to bond GaN with the Si material, and the outermost layer of the bonding layer 4 has a gold (Au) layer, so that the LED chip has good electrical conduction for a convenient use.

The manufacturing method of the LED chip structure of the present invention comprises the steps of:

S1: preparing an epitaxial structure 8;

S2: setting a bonding layer 4 on the epitaxial structure 8 to manufacture an epitaxial material having the bonding layer 4;

S3: transferring the epitaxial material of S2 to a target substrate 1, and bonding the epitaxial material with the target substrate 1 to form a bonding material; and

S4: etching the bonding material described in S3, wherein the bonding material is etched from a bonding layer 4 on a side of the epitaxial material to a substrate to form an LED chip structure.

The epitaxial structure 8 comprises a sapphire substrate 13, a buffer layer 14, and an LED epitaxial layer 3 installed sequentially.

After the epitaxial material and the target substrate 1 in the step S3 are bonded, the sapphire substrate 13 is removed.

The manufacturing method of the present invention has the features of simple manufacture process, easy manufacture, and compact LED chip structure; and the mass transfer method applying the LED chip structure has the features of simple operation, easy alignment, and convenient transfer.

In the mass transfer method applying the LED chip structure of the present invention, the LED chip structure is implanted into a template 9, and the substrate is removed (by dipping the structure into an acidic solution such as hydrochloric acid solution), and then the LED chip is transferred into a target base plate 10 for die bonding, wherein the template 9 has a wax layer 11 near the LED chip structure, and the target base plate 10 has a limit structure 12 for limiting the position of the LED chip structure, and during a mass transfer process, the LED chip to be implanted into the template 9 is dipped into a liquid, and the target base plate 10 is also placed into the liquid, and the buoyancy of the liquid pushes and delivers the target base plate 10 to a position under the LED chip, and after the LED chip is completely engaged with the limit structure 12 of the target base plate 10. In this process, it is necessary to select a common positioning method such as lithography, secondary lithography or engraving process for the positioning purpose in order to improve the precision of the transfer. After the target base plate 10 is engaged with the LED chip, the combined structure is removed from the surface of the liquid, and the template 9 is removed by the slightly melted part of the wax layer 11, and then a die bonding of the LED chip and the target base plate 10 is performed, and finally the wax layer is completely melted and removed to complete the mass transfer of the LED chip structure. Wherein, the liquid used to provide the buoyance to the target base plate 10 and the LED chip is an organic solvent with a smaller density such as ethanol and acetone. Of course, other inorganic solvents or water can be used, but the use of these solvents or water requires a drying process after the mass transfer is completed. If ethanol or acetone is used, then the liquid on the surface of the chip will be vaporized automatically without the need of drying. The mass transfer method of the present invention transfers a large quantity of LED chips by the etching process. During the mass transfer, the template 9 is set to limit the position of the LED chip, but the wax layer 11 is pre-set at the junction of the template 9 and the LED chip, so that it is very easy to melt the wax layer 11 by heat after the mass transfer is completed. When a part of the wax layer 11 is melted, the template 9 will be loosened and can be removed directly. After the subsequent manufacturing processes are completed, the wax layer 11 can be melted completely and removed. However, it is not necessary to remove the whole wax layer 11 during the manufacturing process, since this wax layer 11 can provide a protective effect to the LED chips. In the mass transfer method of the present invention, the structure to be transferred is dipped into a liquid, so that the mass transfer can be completed easily by the buoyancy of the liquid together with the limit structure to avoid the conventional mass transfer that requires a precise alignment of the chips and prevent the position of a single chip from being shifted during the mass transfer, so that this method is convenient for transferring a large quantity of LED chips.

While the invention has been described by means of specific embodiments, numerous modifications and variations could be made thereto by those skilled in the art without departing from the scope and spirit of the invention as set forth in the claims.

What is claimed is:

1. An LED chip structure, comprising a substrate, a light emitting unit coupled to the substrate, a passivation layer, an ohmic contact layer, and a metal layer disposed at the junction of the light emitting unit and the substrate, and the passivation layer being disposed around the periphery of the light emitting unit and coupled to the metal layer, and the ohmic contact layer covering the passivation layer and being coupled to the light emitting unit.

2. The LED chip structure as claimed in claim 1, wherein the light emitting unit comprises an LED epitaxial layer, a bonding layer and a buffer layer installed sequentially, and the LED epitaxial layer is coupled to the metal layer.

3. The LED chip structure as claimed in claim 1, wherein the substrate is made of an etchable material.

4. The LED chip structure as claimed in claim 1, wherein the substrate is made of silicon.

5. The LED chip structure as claimed in claim 2, wherein the bonding layer is made of NiAu, and the outermost layer of the bonding layer has an Au layer.

6. A manufacturing method of the LED chip structure as claimed in any one of claim 1, comprising the steps of:
S1: preparing an epitaxial structure;
S2: setting a bonding layer onto the epitaxial structure to manufacture an epitaxial material having the bonding layer;
S3: transferring the epitaxial material of S2 to a target substrate, and bonding the epitaxial material with the target substrate to form a bonding material; and
S4: etching the bonding material of the step S3, wherein the bonding material is etched from a bonding layer on a side of the epitaxial material to a substrate to form an LED chip structure.

7. The manufacturing method of the LED chip structure as claimed in claim 6 and applied for Micro LED displayed mass transfer, characterized in that the epitaxial structure comprises a sapphire substrate, a buffer layer and an LED epitaxial layer installed sequentially.

8. The manufacturing method of the LED chip structure as claimed in claim 6 and applied for a Micro LED display mass transfer, characterized in that after the epitaxial material and the target substrate in the step S3 are bonded, the sapphire substrate is removed.

9. A mass transfer method of applying the LED chip structure as claimed in any one of claim 1, characterized in that the LED chip structure is implanted with a corresponding template, the substrate is removed, and the LED chip is transferred into a target base plate for die bonding.

10. The mass transfer method of applying the LED chip structure as claimed in claim 9, wherein the template has a wax layer near the LED chip structure, and the target base plate has a limit structure for limiting the position of the LED chip structure, and during a mass transfer process, the LED chip to be implanted into the template is dipped into a liquid, and the target base plate is also placed into the liquid, and the buoyancy of the liquid pushes and delivers the target base plate to a position under the LED chip, and after the LED chip is completely engaged with the limit structure of the target base plate, the target base plate engaged with the LED chip is removed from the surface of the liquid, and the template is removed by the slightly melted part of the wax layer, and then a die bonding of the LED chip and the target base plate is performed, and finally the wax layer is completely melted and removed to complete the mass transfer of the LED chip structure.
